(19) United States
(12) Patent Application Publication
(10) Pub. No.: US 2014/0242811 A1
(43) Pub. Date: Aug. 28, 2014

(54) ATOMIC LAYER DEPOSITION METHOD

(71) Applicant: UNITED MICROELECTRONICS CORP., Hsin-Chu City (TW)

(72) Inventors: Jui-Chen Chang, Kaohsiung City (TW); Chen-Kuo Chiang, Tainan City (TW); Chin-Fu Lin, Tainan City (TW); Chih-Chien Liu, Taipei City (TW)

(73) Assignee: UNITED MICROELECTRONICS CORP., Hsin-Chu City (TW)

(21) Appl. No.: 13/778,147

(22) Filed: Feb. 27, 2013

(51) Int. Cl. H01L 21/02

(52) U.S. Cl. CPC H01L 21/0228
USPC 438/785

(57) ABSTRACT

An ALD method includes providing a substrate in an ALD reactor, performing a pre-ALD treatment to the substrate in the ALD reactor, and performing one or more ALD cycles to form a dielectric layer on the substrate in the ALD reactor. The pre-ALD treatment includes providing a hydroxylating agent to the substrate in a first duration, and providing a precursor to the substrate in a second duration. Each of the ALD cycles includes providing the hydroxylating agent to the substrate in a third duration, and providing the precursor to the substrate in a fourth duration. The first duration is longer than the third duration.

### BACKGROUND OF THE INVENTION

1. Field of the Invention

The invention relates to an atomic layer deposition (hereinafter abbreviated as ALD) method, and more particularly, to an ALD method for the formation of high dielectric constant (hereinafter abbreviated as high-k) thin film.

2. Description of the Prior Art

Current VLSI technology uses silicon dioxide (SiO₂) as the gate dielectric layer in metal-oxide-semiconductor (MOS) devices. Typically, SiO₂ has a dielectric constant of 3.9, while it would be desirable to use gate dielectric material with a dielectric constant of greater than approximately 10. Therefore, high-k metal oxides have been considered as possible alternative materials to SiO₂ to provide gate dielectrics with high capacitance but without compromising the leakage current.

Deposition of high-k metal oxides, using ALD method has been reported to replace conventional chemical vapor deposition (CVD) for meeting the requirements of forming these advanced thin films. ALD method has several advantages over CVD: ALD can be performed at relative low temperature, has high precursor utilization efficiency, and produces conformal thin film layers. However, it is found that non-continuous “island” is formed at a nucleation stage of the metal oxide film growth and it results in films that are rough with poor uniformity.

Therefore, it is necessary to provide an ALD method for forming high-k thin film have superior uniformity.

### SUMMARY OF THE INVENTION

According to the claimed invention an ALD method is provided. The ALD method includes providing a substrate in an ALD reactor, performing a pre-ALD treatment to the substrate in the ALD reactor, and performing one or more ALD cycles to form a dielectric layer on the substrate in the ALD reactor. The pre-ALD treatment includes providing a hydroxylating agent to the substrate in a first duration, and providing a precursor to the substrate in a second duration. Each of the ALD cycles includes providing the hydroxylating agent to the substrate in a third duration, and providing the precursor to the substrate in a fourth duration. It is noteworthy that the first duration is longer than the third duration.

According to the ALD method provided by the present invention, the pre-ALD treatment is performed to form an OH-rich surface of the substrate in advance of performing the ALD cycles. Accordingly, the deposition of the dielectric layer is initiated at the OH-rich surface and thus the dielectric layer formed by the ALD cycles obtains a superior uniformity.

These and other objectives of the present invention will no doubt become obvious to those of ordinary skill in the art after reading the following detailed description of the present invention that is illustrated in the various figures and drawings.

### BRIEF DESCRIPTION OF THE DRAWINGS

FIG. 1 is a flow chart illustrating an ALD method provided by the present invention.

FIGS. 2-7 are schematic drawings illustrating the ALD method provided by the present invention, wherein

FIG. 3 is a schematic drawing in a step subsequent to FIG. 2,

FIG. 4 is a schematic drawing in a step subsequent to FIG. 3,

FIG. 5 is a schematic drawing in a step subsequent to FIG. 4,

FIG. 6 is a schematic drawing in a step subsequent to FIG. 5, and

FIG. 7 is a schematic drawing in a step subsequent to FIG. 6.

### DETAILED DESCRIPTION

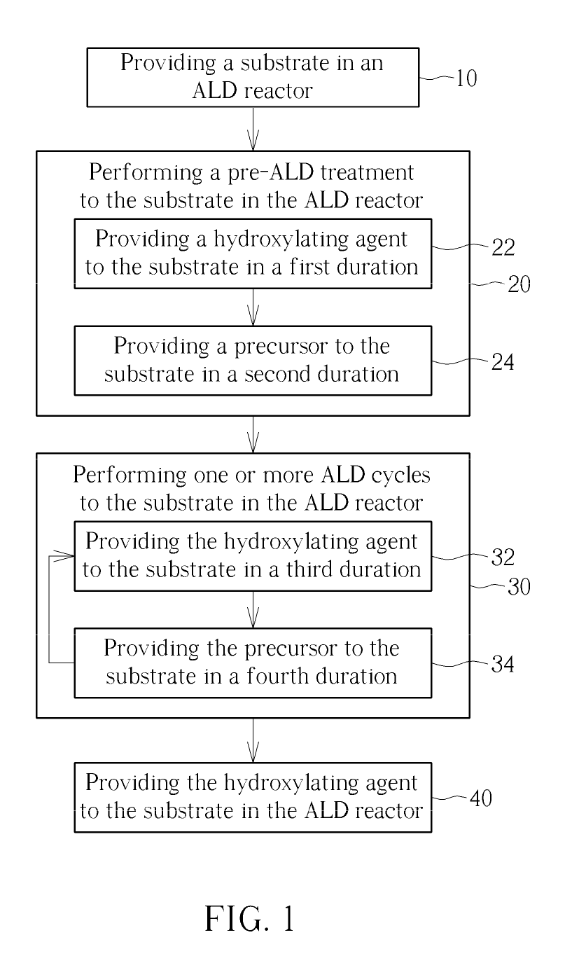

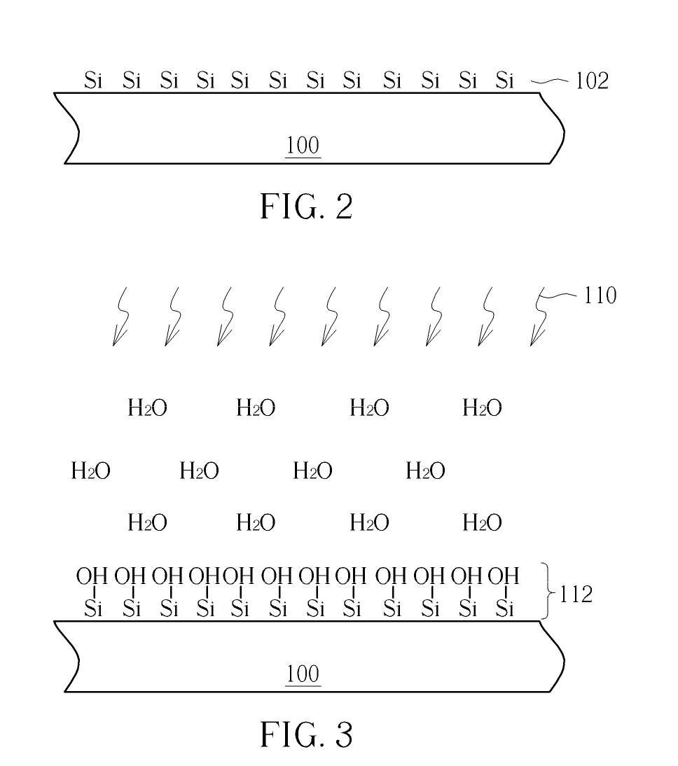

The invention will be described in the following in greater detail with reference to the attached drawings of which: FIG. 1 is a flow chart illustrating an ALD method provided by the present invention, and FIGS. 2-7 are schematic drawings illustrating the ALD method provided by the present invention.

As shown in FIG. 1 and FIG. 2, the ALD method provided by the present invention is performed with:

STEP 10: providing a substrate in an ALD reactor.

Commercial ALD tools are now becoming available, therefore those details are omitted herein in the interest of brevity. The substrate preferably is a Si-substrate 100. The Si-substrate 100 is pre-cleaned to remove native oxides which may have formed over the substrate surface. Consequently, a Si-surface 102 is obtained as shown in FIG. 2. Parenthetically speaking, it is observed that the pre-clean may form a portion of silicon-hydrogen (Si—H) surface (not shown) of the substrate 100. Next, the ALD method is performed with:

STEP 20: Performing a pre-ALD treatment.

It is noteworthy that the pre-ALD treatment further includes two steps, which is detailed as following:

STEP 22: providing a hydroxylating agent to the substrate in a first duration.

As shown in FIG. 3, the Si-surface 102 (and/or the Si—H surface) of the substrate 100 is treated with a hydroxylating agent 110 in a first duration D1. In the present invention, the hydroxylating agent 110 includes hydrogen oxide (H₂O), but not limited to this. Consequently, the Si-surface 102 of the substrate 100 is transferred to a Si—OH surface 112. It should be noted that in order to obtain an OH-rich surface, preferably to obtain a surface saturated with OH bonds, the first duration D1 is the longest process duration among the whole ALD method. The first duration D1 even can be prolonged to the limitation of the ALD reactor.

After providing the hydroxylating agent 110, a non-reactive gas is provided to purge the hydroxylating agent 110 and/or any possible undesirable reactants out of the ALD reactor and to stop the hydroxylation. The non-reactive gas includes nitrogen (N₂), but not limited to this. Those skilled in the art would easily realize that an inert gas, such as argon (Ar), helium (He), or neon (Ne) can be introduced to purge the ALD reactor.

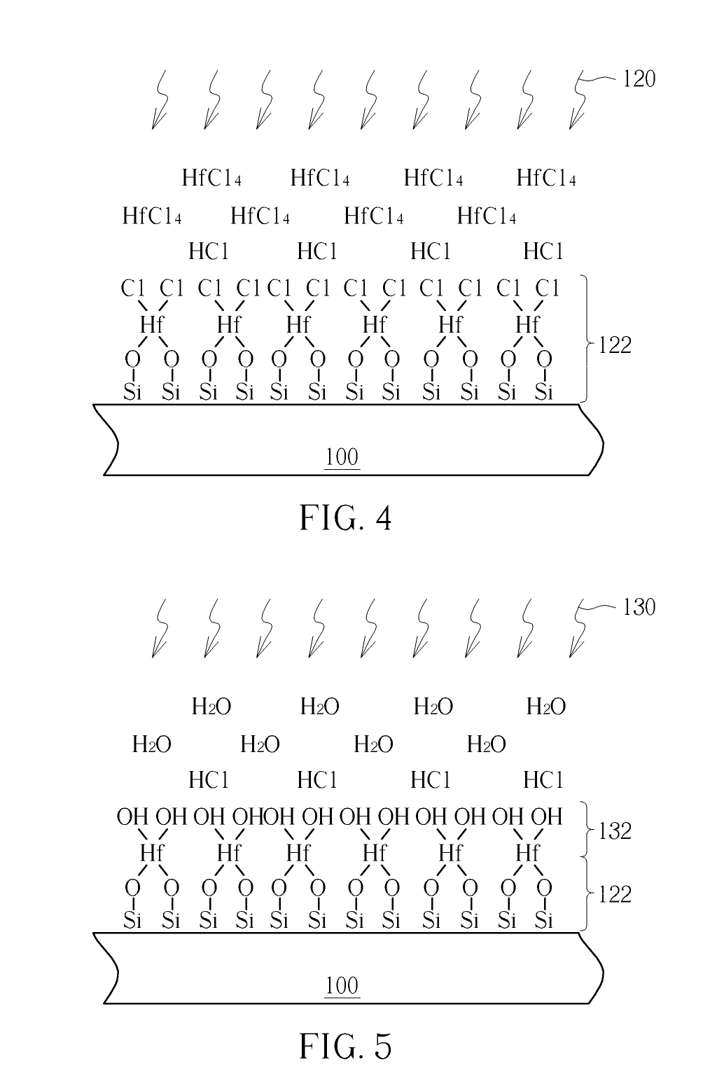

Please refer to FIG. 1 and FIG. 4. Then, a next step of the pre-ALD treatment is performed:

STEP 24: Providing a precursor to the substrate in a second duration.

Please refer to FIG. 4, the Si—OH surface 112 of the substrate 100 is treated with a precursor 120 in a second duration D2. In the present invention, the precursor 120 includes hafnium-containing gas, such as hafnium tetrachloride (HfCl₄), but not limited to this. Consequently, O—H bond of the Si—OH surface 112 of the substrate 100 is broken, and an initial Hf-monolayer 122 having a Cl—H—Cl surface is formed as shown in FIG. 4. It should be noted to that the hydrogen of OH-bond is easily replaced with HfCl₂ and thus the initial Hf monolayer 122 is obtained and preparatory to the following ALD process. More important, since the surface of the substrate 100 is saturated with OH by the former STEP 22 as mentioned above, the initial Hf monolayer 122 is much easier obtained and no islanding configuration is made.

After providing the precursor 120, the non-reactive gas is also provided to purge the precursor 120 and/or any possible undesirable reactants out of the ALD reactor. In other words, the non-reactive gas is introduced into the ALD reactor respectively after providing the hydroxylating agent and after providing the precursor in the pre-ALD treatment.

After the pre-ALD treatment, the ALD method is performed with:

STEP 30: Performing one or more ALD cycles in the ALD reactor.

It is noteworthy that each of the ALD cycles further includes two steps, which is detailed as following:

STEP 32: providing the hydroxylating agent to the substrate in a third duration.

As shown in FIG. 5, the Cl—Hf—Cl surface of the initial Hf monolayer 122 on the substrate 100 is treated with the hydroxylating agent 130 in a third duration D3. In the present invention, the hydroxylating agent 130 also includes H₂O, but not limited to this. Consequently, the initial Hf monolayer 122 of the substrate 100 is transferred to an OH-rich surface 132. It should be noted that since Cl is easily replaced by OH, the OH-rich surface 132 is obtained within a shorter process duration.

After providing the hydroxylating agent 130, the non-reactive gas again is provided to purge the hydroxylating agent 130 and/or any possible undesirable reactants out of the ALD reactor and to stop the hydroxylation. The non-reactive gas includes N₂, but not limited to this.

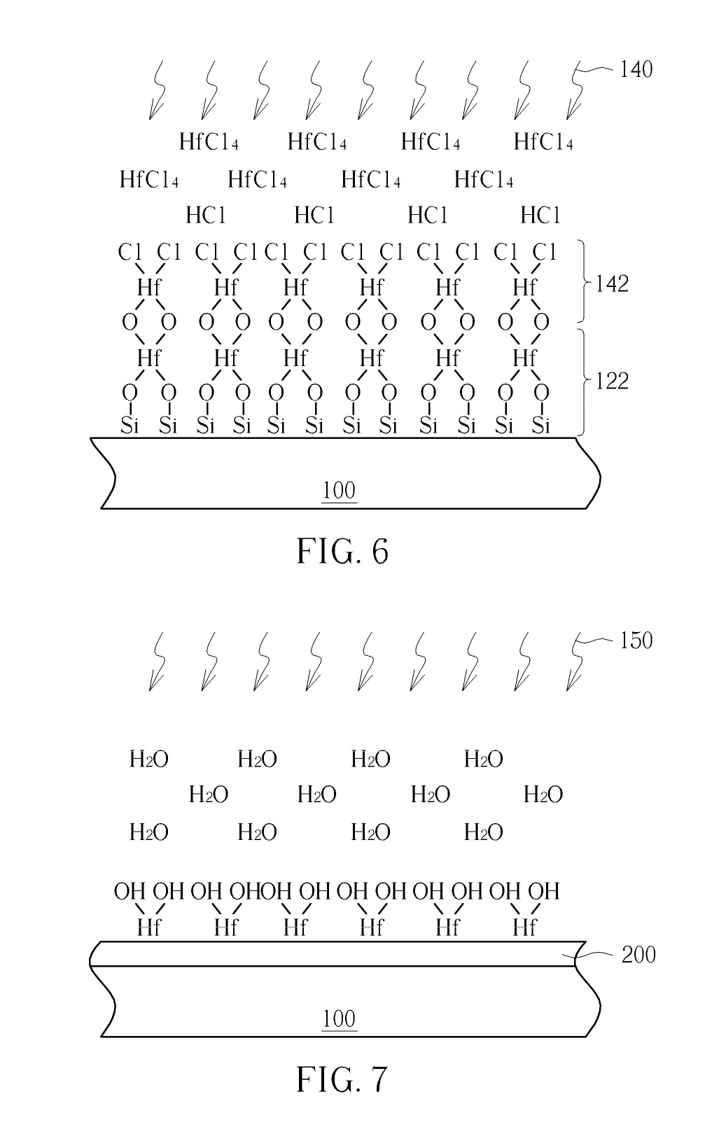

Please refer to FIG. 1 and FIG. 6. Then, a next step of each ALD cycle is performed:

STEP 34: Providing the precursor to the substrate in a fourth duration.

As shown in FIG. 6, the OH-rich surface 132 of the initial Hf monolayer 122 on the substrate 100 is treated with a precursor 140 in a fourth duration D2. In the present invention, the precursor 140 also includes HfCl₄, but not limited to this. Those skilled in the art would easily realize that zirconium tetrachloride (ZrCl₄) may be involved in the ALD cycles. Consequently, the O—H bond of the OH-rich surface 132 of the initial Hf monolayer 122 is broken, and an Hf monolayer 142 is formed on the initial Hf monolayer 122. After providing the precursor 140, the non-reactive gas again is provided to purge the precursor 140 and/or any possible undesirable reactants out of the ALD reactor. In other words, the non-reactive gas is introduced respectively after providing the hydroxylating agent 130 and after providing the precursor 140 in each of the ALD cycles.

It should be noted that the ALD cycle can be repeated any number of times (“M” as shown in the following tables) until a dielectric layer of desired thickness is formed. In other words, the repetition of STEP 32 and STEP 34 to produce an Hf monolayer is made to achieve the desired thickness. For example, 6 ALD cycles and 10 ALD cycles can be performed with HfCl₄ serving as the precursor while 4 ALD cycles with ZrCl₄ serving as the precursor can be intervened therebetween.

Additionally, after performing the ALD cycles, a post step is performed:

STEP 40: Providing the hydroxylating agent to the substrate in the ALD reactor.

As shown in FIG. 7, after performing numbers of ALD cycles and a dielectric layer 200 is accordingly formed, the STEP 40 is performed to form an OH—Hf—OH surface 202 of the dielectric layer 200 and to close the ALD method with providing the hydroxylating agent 150 that is H₂O.

Comparing the STEP 22 of the pre-ALD treatment and the STEP 32 of each ALD cycle, it is observed that in the present invention, a flow rate of the hydroxylating agent 110 in the pre-ALD treatment and a flow rate of the hydroxylating agent 130 in each of the ALD cycles are the same. In the same concept, a temperature of the hydroxylating agent 110 in the pre-ALD treatment and a temperature of the hydroxylating agent 130 in each of the ALD cycles are the same. Comparing the STEP 24 of the pre-ALD treatment and the STEP 34 of each ALD cycle, it is also observed that in the present invention, a flow rate of the precursor 120 in the pre-ALD treatment and a flow rate of the precursor 140 in each of the ALD cycles are the same. In the same concept, a temperature of the precursor 120 in the pre-ALD treatment and a temperature of the precursor 140 in each of the ALD cycles are the same, and a concentration of the precursor 120 in the pre-ALD treatment and a concentration of the precursor 140 in each of the ALD cycles are the same.

Please refer to Table 1 which illustrates a preferred embodiment provided by the present invention. Most important, the first duration D1 of providing the hydroxylating agent 110 in the pre-ALD treatment is longer than the third duration D3 of providing the hydroxylating agent 130 in each of the ALD cycles for obtaining the Si—OH surface 112 as shown in FIG. 3. Specifically, the first duration D1 is 5-20 times over the third duration D3 according to different requirements. In other preferred embodiment, the first duration D1 of providing the hydroxylating agent 110 in the pre-ALD treatment can be also longer than the second duration D2 of providing the precursor 120 in the pre-ALD treatment since the Cl—Hf—Cl bond is easily replaced with the OH—Hf—OH bond as shown in FIG. 4. For example but not limited to, the first duration D1 is two times over the second duration D2. On the other hand, the second duration D2 of providing the precursor 120 in the pre-ALD treatment is longer than the fourth duration D4 of providing the precursor 140 in each of the ALD cycles. Specifically, the second duration D2 is 5-10 times over the fourth duration D4. It should be noted that “N” recited in Table 1 is a natural number.

### Embodiment 1

TABLE 1

| | pre-ALD treatment | | | | | ALD cycle | | | | |
|---|---|---|---|---|---|---|---|---|---|---|
| agent | H₂O | N₂ | HfCl₄ | N₂ | Cycle | H₂O | N₂ | HfCl₄/ZrCl₄ | N₂ | Cycle |
| sec. | 5 * N | X1 * N | 5 * N | 1 * N | M | 1 * N | 1 * N | 1 * N | 1 * N | M |

N = 1-9
M = 1-9

According to the preferred embodiment as shown above, it is observed that the first duration D1 of the STEP 22, which is providing the hydroxylating agent to the substrate 100 in the ALD reactor, is the longest step among the whole ALD method. Furthermore, it is observed that the third duration D3 of the STEP 32, which is providing the precursor to the substrate 100 in the ALD reactor, can be further shortened as shown in Table 1. In other words, the overall process duration of the ALD method is reduced according to the second preferred embodiment. On the other hand, since the initial Hf monolayer 122 serves as a uniform platform for forming the Hf monolayer 122, the ALD cycle numbers can be reduced when comparing with the conventional ALD method.

According to the ALD method provided by the present invention, the pre-ALD treatment is performed to form an OH-rich surface of the substrate in advance of performing the ALD cycles. Accordingly, the deposition of the dielectric layer is initiated at the OH-rich surface and thus the dielectric stacked layer obtained by performing the ALD cycles includes a superior uniformity. The second advantage of the ALD method provided by the present invention is that the pre-ALD treatment and the ALD cycles are all performed in the one ALD reactor. And the third advantage of the ALD method provided by the present invention is that the process duration of providing the precursor to the substrate in the ALD reactor can be reduced or the ALD cycle numbers can be reduced and thus the overall process duration is shortened.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An atomic layer deposition (ALD) method comprising:
providing a substrate in an ALD reactor;
performing a pre-ALD treatment to the substrate in the ALD reactor, the pre-ALD treatment comprising:
providing a hydroxylating agent to the substrate in a first duration; and
providing a precursor to the substrate in a second duration; and
performing one or more ALD cycles to form a dielectric layer on the substrate in the ALD reactor, each of the ALD cycles comprising:
providing the hydroxylating agent to the substrate in a third duration; and
providing the precursor to the substrate in a fourth duration,
wherein the first duration is longer than the third duration.

2. The ALD method according to claim 1, wherein the hydroxylating agent comprises H₂O.

3. The ALD method according to claim 1, wherein the precursor comprises HfCl₄.

4. The ALD method according to claim 1, wherein the first duration is 5-20 times over the third duration.

5. The ALD method according to claim 1, wherein the first duration is longer than the second duration.

6. The ALD method according to claim 1, wherein the second duration is longer than the fourth duration.

7. The ALD method according to claim 6, wherein the second duration is 5-10 times over the fourth duration.

8. The ALD method according to claim 1, wherein a flow rate of the hydroxylating agent in the pre-ALD treatment and a flow rate of the hydroxylating agent in each of the ALD cycles are the same.

9. The ALD method according to claim 1, wherein a flow rate of the precursor in the pre-ALD treatment and a flow rate of the precursor in each of the ALD cycles are the same.

10. The ALD method according to claim 1, wherein a temperature of the hydroxylating agent in the pre-ALD treatment and a temperature of the hydroxylating agent in each of the ALD cycles are the same.

11. The ALD method according to claim 1, wherein a temperature of the precursor in the pre-ALD treatment and a temperature of the precursor in each of the ALD cycles are the same.

12. The ALD method according to claim 1, wherein a concentration of the precursor in the pre-ALD treatment and a concentration of the precursor in each of the ALD cycles are the same.

13. The ALD method according to claim 1, further comprising providing a non-reactive gas respectively after providing the hydroxylating agent and after providing the precursor in the pre-ALD treatment.

14. The ALD method according to claim 13, further comprising providing the non-reactive gas respectively after providing the hydroxylating agent and after providing the precursor in the pre-ALD treatment.

15. The ALD method according to claim 14, wherein the non-reactive gas comprises N₂.
